(19) United States
(12) Patent Application Publication
(10) Pub. No.: US 2025/0105087 A1
(43) Pub. Date: Mar. 27, 2025

(54) CHIP PACKAGE HAVING HEAT DISSIPATION STRUCTURE AND MANUFACTURING METHOD THEREOF

(71) Applicant: SAMSUNG ELECTRONICS CO., LTD., Suwon-si (KR)

(72) Inventor: Chunyan RUAN, Suzhou (CN)

(73) Assignees: SAMSUNG ELECTRONICS CO., LTD., Suwon-si (KR); SAMSUNG SEMICONDUCTOR CHINA RESEARCH & DEVELOPMENT CO., LTD., Suzhou (CN)

(21) Appl. No.: 18/593,300

(22) Filed: Mar. 1, 2024

(30) Foreign Application Priority Data
Sep. 21, 2023 (CN) 202311221306.5

(51) Int. Cl. H01L 23/367; H01L 23/00; H01L 23/498

(52) U.S. Cl. CPC H01L 23/3675; H01L 24/16; H01L 24/32; H01L 24/33; H01L 24/73; H01L 23/4985; H01L 24/83; H01L 24/92; H01L 2224/16227; H01L 2224/32225; H01L 2224/32245; H01L 2224/33181; H01L 2224/73204; H01L 2224/83192; H01L 2224/92125

(57) ABSTRACT

A chip package includes: a flexible substrate including a bottom surface, a side wall, and a top surface including a central region and an edge region; a first heat dissipation part including a body part and a wing part on the bottom surface and extending from opposite ends of the body part to the top surface along the side wall, the wing part covering the edge region; a semiconductor chip on the top surface; a second heat dissipation part covering an upper surface of the semiconductor chip, and a portion of the wing part that covers the edge region; and a heat dissipation glue on a lower surface of the second heat dissipation part, wherein the heat dissipation glue connects the semiconductor chip to the second heat dissipation part and connects the second heat dissipation part to the first heat dissipation part, to form a heat dissipation path.

### CROSS-REFERENCE TO RELATED APPLICATION

This application claims priority to Chinese Patent Application No. 202311221306.5, filed on Sep. 21, 2023, in the China National Intellectual Property Administration, the disclosure of which is incorporated by reference herein in its entirety.

### BACKGROUND

### 1. Field

The present disclosure relates to a semiconductor package field and, more particularly, to a chip package having a heat dissipation structure and a manufacturing method thereof.

### 2. Description of Related Art

In order to meet the demand for driver integrated circuits (IC) s of higher scaling and/or running speeds, various packages have been proposed. For example, a Tape Carrier Package (TCP), a Chip On Glass (COG) package and a Chip On Film package may be used as packages of the driver ICs of display panels. In order to realize display devices of high-resolutions (e.g., LCD panels), the refresh frequency of the display devices has increased from 60 HZ to 120 HZ. This causes an increase of the load of the driver IC, and the problem of heat dissipation of the package of the driver IC needs to be solved.

FIG. 1 illustrates a COF-type semiconductor package according to the related art. As illustrated in FIG. 1, an upper heating pad 22 as a heat dissipation plate is disposed on a top surface of a chip 18 via an adhesive layer 21. Because a contact area between the upper heating pad 22 and the chip 18 is limited, the heat dissipation efficiency is restricted.

FIG. 2 illustrates a COF-type semiconductor package according to the related art. As illustrated in FIG. 2, a lower heating pad 20 as the heat dissipation plate is disposed on a film substrate 10 via the adhesive layer 21. Because the film substrate 10 has a lower thermal conductivity than a metal, and the lower heating pad 20 does not directly contact the chip 18, the heat dissipation effect is not good.

### SUMMARY

Embodiments of the present disclosure provide a chip package having a heat dissipation structure and a manufacturing method thereof that may improve the heat dissipation effect.

According to an aspect of an example embodiment, a chip package includes: a flexible substrate including a bottom surface, a side wall, and a top surface including a central region and an edge region around the central region; a first heat dissipation part including a body part and a wing part on the bottom surface of the flexible substrate and extending from opposite ends of the body part to the top surface of the flexible substrate along the side wall of the flexible substrate, the wing part covering the edge region of the top surface of the flexible substrate; a semiconductor chip on the top surface of the flexible substrate; a second heat dissipation part covering an upper surface of the semiconductor chip, and a portion of the wing part of the first heat dissipation part that covers the edge region of the top surface of the flexible substrate; and a heat dissipation glue on a lower surface of the second heat dissipation part, wherein the heat dissipation glue connects the semiconductor chip to the second heat dissipation part and connects the second heat dissipation part to the first heat dissipation part, to form a heat dissipation path.

According to an aspect of an example embodiment, a method of manufacturing a chip package, includes: disposing a first heat dissipation part on a flexible substrate, wherein the flexible substrate includes a bottom surface, a side wall, and a top surface including a central region and an edge region provided around the central region, and the first heat dissipation part includes a body part and a wing part extending from opposite ends of the body part to the top surface of the flexible substrate along the side wall of the flexible substrate, and covering the edge region of the top surface of the flexible substrate; disposing a semiconductor chip on the top surface of the flexible substrate; disposing a heat dissipation glue on a lower surface of a second heat dissipation part; and disposing the second heat dissipation part on the semiconductor chip and the flexible substrate, wherein the second heat dissipation part covers an upper surface of the semiconductor chip and a portion of the wing part of the first heat dissipation part that covers the edge region of the top surface of the flexible substrate, and the heat dissipation glue connects the semiconductor chip to the second heat dissipation part, and connects the second heat dissipation part to the first heat dissipation part, to form a heat dissipation path.

### BRIEF DESCRIPTION OF THE DRAWINGS

The above and other aspects, features and advantages of the present disclosure will be more apparent from the following detailed description of example embodiments, taken in conjunction with drawings, in which:

FIG. 1 illustrates a chip package according to the related art;

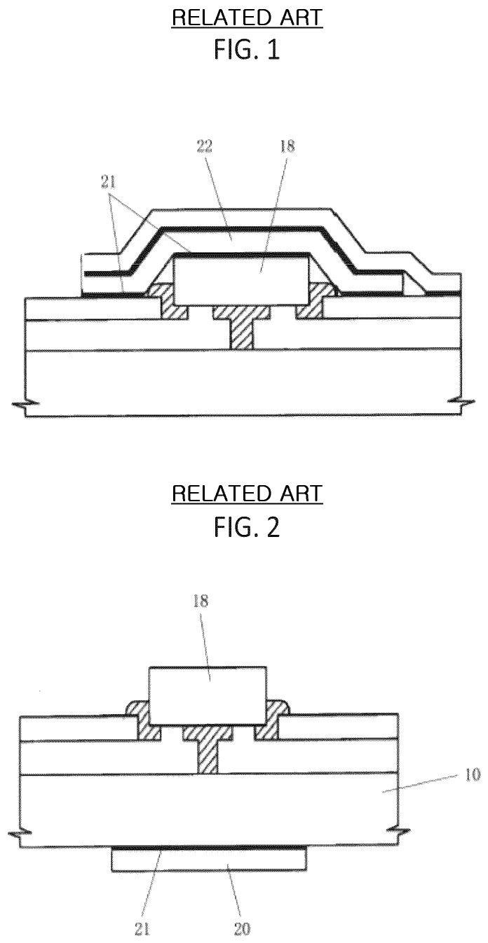

FIG. 2 illustrates a chip package according to the related art;

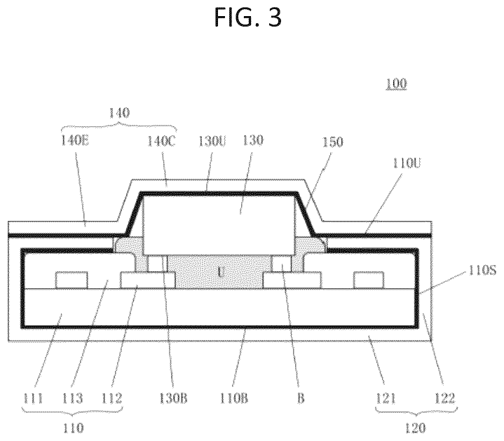

FIG. 3 illustrates a chip package according to one or more example embodiments;

FIG. 4 illustrates a chip package according to one or more example embodiments of one or more example embodiments;

FIG. 5 is a flowchart illustrating a method of manufacturing a chip package according to one or more example embodiments;

FIGS. 6A, 6B, 6C and 6D are diagrams illustrating intermediate steps of a method of manufacturing the chip package illustrated in FIG. 3 according to one or more example embodiments; and

FIGS. 7A and 7B are diagrams illustrating intermediate steps of a method of manufacturing the chip package illustrated in FIG. 4 according to one or more example embodiments.

### DETAILED DESCRIPTION

Example embodiments will be described in detail below by referring to the drawings. However, embodiments of the present disclosure may be implemented in many different forms, and should not be interpreted to be limited to the embodiments elaborated hereto. In the drawings, to be clear, sizes of a layer and an area may be exaggerated. The same reference numerals are used for the same components in the drawings, and duplicate descriptions thereof are omitted.

For easy description, spatial relevancy terms (such as “below”, “under”, “above”, “on”, etc.) are used herewith with reference to one or more example embodiments to describe a relationship between one component and the other component as illustrated in the drawings. It should be understood that, the spatial relevancy terms also intend to include different orientations of a device in a usage or an operation, other than the orientations as described in the drawings. For example, if the device in the drawings is flipped, the component described to be “below” or “under” the other component may be modified as “above” the other component. Therefore, the term “below” may include the “upper” and “lower” orientations. The device can be directed towards another orientation (e.g., rotated by 90 degrees or located in another orientation), and the spatial relevancy terms used herein should be interpreted accordingly.

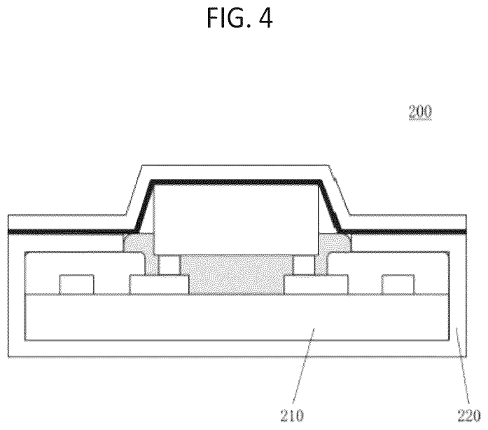

FIG. 3 illustrates a chip package according to one or more example embodiments. As illustrated in FIG. 3, a chip package 100 includes: a flexible substrate 110, a first heat dissipation part 120, a semiconductor chip 130, a second heat dissipation part 140 and a heat dissipation glue 150. The chip package 100 may be a COF-type package. The chip package 100 may be a driver IC included in a display device (e.g., a LCD panel).

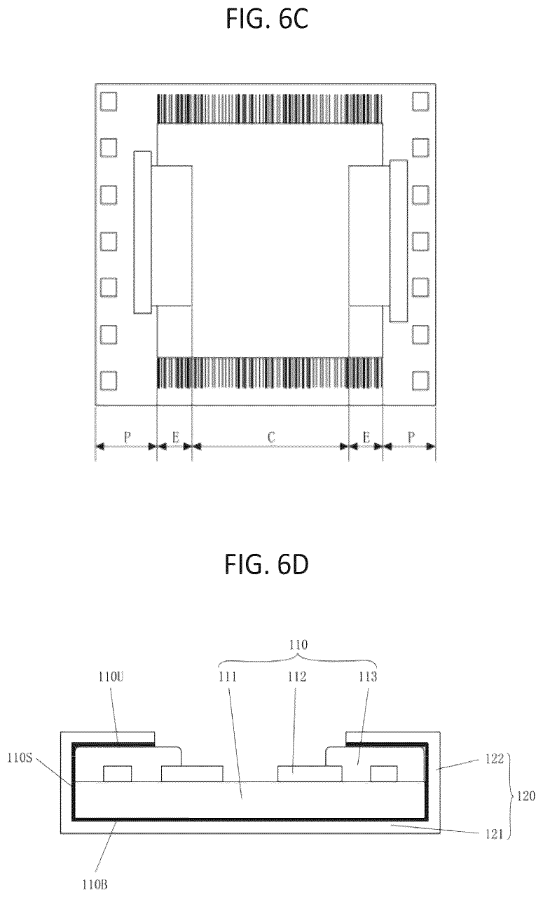

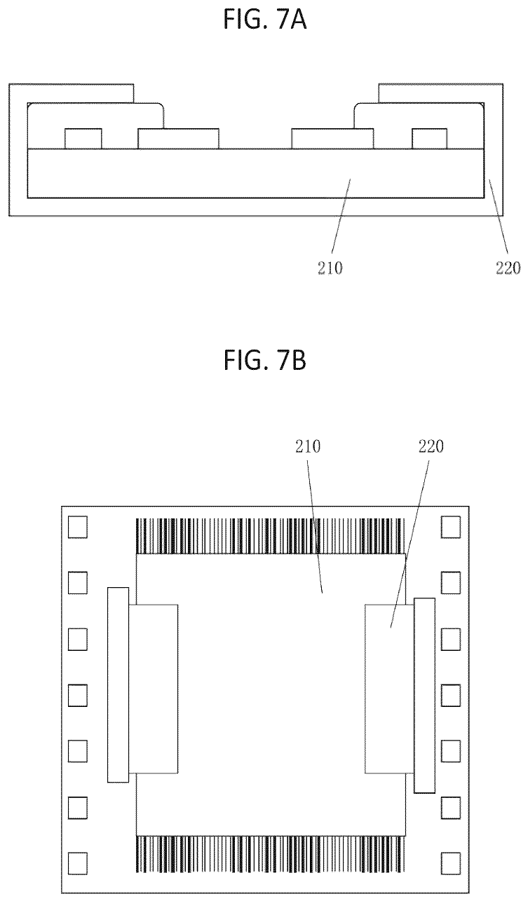

In one or more example embodiments, as illustrated in FIG. 3, the flexible substrate 110 may include a bottom surface 110B, a side wall 110S and a top surface 110U. In a plan view, the top surface 110U of the flexible substrate 110 may include a central region C and an edge region E surrounding the central region C. In addition, in one or more example embodiments, as illustrated in FIGS. 6C and 7B, the top surface 110U of the flexible substrate 110 may further include a peripheral region P surrounding the edge region E.

In one or more example embodiments, as illustrated in FIG. 3, the flexible substrate 110 may include: a base film 111, a wiring layer 112 and a solder resist 113. For example, the base film 111 may be formed of a flexible material, and thus may have a bendable or rollable or foldable flexibility. The wiring layer 112 may be disposed on an upper surface of the base film 111. In one or more example embodiments, the wiring layer 112 may be formed of a conductive material. For example, the wiring layer 112 may be formed of a metal such as copper or silver. The solder resist 113 may cover the wiring layer 112. In one or more example embodiments, the solder resist 113 may cover a portion of the wiring layer 112, and expose a portion of the wiring layer 112 that is connected to an external element.

In one or more example embodiments, as illustrated in FIGS. 6C and 7B, the solder resist 113 may be disposed in the central region C and the edge region E, but may not be disposed in the peripheral region P.

In one or more example embodiments, as illustrated in FIGS. 3 and 6A, the first heat dissipation part 120 may include a body part 121 and a wing part 122 connected at both sides of the body part 121. The body part 121 may be disposed on the bottom surface 110B of the flexible substrate 110. The wing part 122 may extend to the top surface 110U of the flexible substrate 110 along the side wall 110S of the flexible substrate 110, and cover the edge region E of the top surface 110U of the flexible substrate 110.

In one or more example embodiments, as illustrated in FIG. 6A, the wing part 122 of the first heat dissipation part 120 may extend from both sides of the body part 121 to a certain length. The length may be sufficient to cover the side wall 110S of the flexible substrate 110 to extend to a level higher than the top surface 110U of the flexible substrate 110.

In one or more example embodiments, as illustrated in FIG. 6A, the body part 121 of the first heat dissipation part 120 may have a first length L1. The wing part 122 of the first heat dissipation part 120 may have a first width W1. The first length L1 may be larger than the first width W1. Each of the body part 121 and the wing part 122 of the first heat dissipation part 120 may have a rectangular shape. However, one or more example embodiments are not limited thereto, and depending on the shape and size of the flexible substrate, the first heat dissipation part may have a different shape and size. In addition, the first heat dissipation part may further have a wing part at each side thereof.

In one or more example embodiments, as illustrated in FIG. 6B, the top surface 110U of the flexible substrate 110 may further include a trench T. The trench T may be disposed in the peripheral region P at both sides of the flexible substrate 110. The trench T may penetrate the flexible substrate 110. In one or more example embodiments, as illustrated in FIG. 6C, the wing part 122 of the first heat dissipation part 120 may pass through the trench T along a vertical direction. Then, as illustrated in FIG. 6D, the wing part 122 of the first heat dissipation part 120 may be bent along a horizontal direction to cover the edge region E of the top surface 110U of the flexible substrate 110.

In one or more example embodiments, the central region C and the edge region E of the top surface 110U of the flexible substrate 110 may have a second length L2. The trench T may have a second width W2. In one or more example embodiments, the second length L2 of the flexible substrate 110 may be larger than or equal to the first length L1 of the body part 121 of the first heat dissipation part 120, and the second width W2 of the trench T may be larger than the first width W1 of the wing part 122 of the first heat dissipation part 120.

In one or more example embodiments, as illustrated in FIG. 3, the semiconductor chip 130 may be disposed on the top surface 110U of the flexible substrate 110. In one or more example embodiments, an upper surface 130U of the semiconductor chip 130 may be a passive surface, and a lower surface 130B of the semiconductor chip 130 may be an active surface. In this case, the semiconductor chip 130 may be connected to the wiring layer 112 of the flexible substrate 110 via a conductive bump B disposed on the active surface. In one or more example embodiments, an underfill material U may be disposed between the semiconductor chip 130 and the flexible substrate 110, and may surround the conductive bump B.

In one or more example embodiments, as illustrated in FIG. 3, the second heat dissipation part 140 may cover the upper surface 130U of the semiconductor chip 130 and a portion of the wing part 122 of the first heat dissipation part 120 covering the edge region E of the top surface 110U of the flexible substrate 110. In one or more example embodiments, the second heat dissipation part 140 may not contact a side surface of the semiconductor chip 130. Although FIG. 3 illustrates that the second heat dissipation part 140 contacts the underfill material U, according to one or more example embodiments, the second heat dissipation part 140 may not contact any element of the flexible substrate 110.

In one or more example embodiments, the first heat dissipation part 120 may not contact the semiconductor chip 130. The portion of the wing part 122 of the first heat dissipation part 120 covering the top surface 110U of the flexible substrate 110 may be separated from the side wall of the semiconductor chip 130 in a horizontal direction.

In one or more example embodiments, both the first heat dissipation part 120 and the second heat dissipation part 140 may be formed of a conductive material such as a metal. For example, the metal may be copper, but one or more example embodiments are not limited thereto, and the heat dissipation parts may be formed by selecting any suitable conductive material. In one or more example embodiments, the first heat dissipation part 120 and the second heat dissipation part 140 may be formed of the same material, but in one or more example embodiments, the first heat dissipation part 120 and the second heat dissipation part 140 may be formed of different materials.

In one or more example embodiments, a thickness of the first heat dissipation part 120 may be 25 μm to 35 μm. A thickness of the second heat dissipation part 140 may be the same as or different from that of the first heat dissipation part 120.

In one or more example embodiments, the first heat dissipation part 120 may be formed to have a pad shape, and the second heat dissipation part 140 may be formed to have a plate shape. In other words, the first heat dissipation part 120 may be a heat dissipation pad, and the second heat dissipation part 140 may be a heat dissipation plate, but one or more example embodiments are not limited thereto.

In one or more example embodiments, as illustrated in FIG. 3, the heat dissipation glue 150 may be disposed on the lower surface of the second heat dissipation part 140. In one or more example embodiments, the second heat dissipation part 140 may include a central portion 140C and an edge portion 140E. The central portion 140C of the second heat dissipation part 140 may contact the upper surface 130U of the semiconductor chip 130 via the heat dissipation glue 150. The edge portion 140E of the second heat dissipation part 140 may contact the portion of the wing part 122 of the first heat dissipation part 120 covering the edge region E of the top surface 110U of the flexible substrate 110 via the heat dissipation glue 150.

In one or more example embodiments, as illustrated in FIG. 3, the heat dissipation glue 150 may further be disposed between the flexible substrate 110 and the first heat dissipation part 120. As such, the first heat dissipation part 120 may be coupled to the flexible substrate 110 through the heat dissipation glue 150.

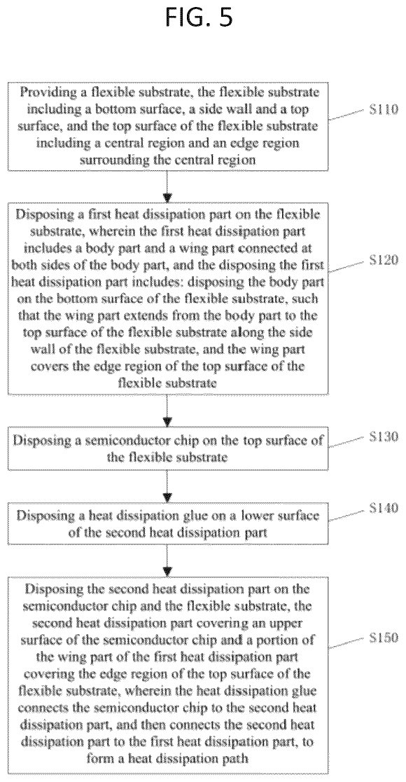

FIG. 4 illustrates a chip package according to one or more example embodiments. As illustrated in FIG. 4, in a chip package 200 according to one or more example embodiments, the heat dissipation glue 150 may not be disposed between a first heat dissipation part 220 and a flexible substrate 210. The first heat dissipation part 220 may be coupled to the flexible substrate 210 through an electroplating layer formed by an electroplating process. A thickness of the electroplating layer may be 25 μm to 35 μm, for example.

According to one or more example embodiments, the heat dissipation glue 150 may connect the semiconductor chip 130 to the second heat dissipation part 140, and then connect the second heat dissipation part 140 to the first heat dissipation part 220, to form a heat dissipation path. The package having the heat dissipation structure according to one or more example embodiments may expand a heat dissipation area in direct contact with a surface of the chip through the first heat dissipation part located on the bottom surface, the side wall and the top surface of the flexible substrate and the second heat dissipation part connected to the upper surface of the COF-type semiconductor chip and the edge of the first heat dissipation part, thereby improving the heat dissipation effect.

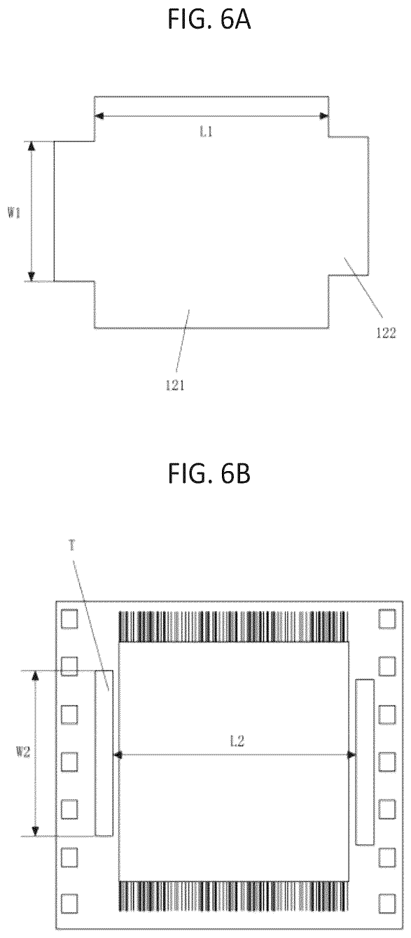

FIG. 5 is a flowchart illustrating a method of manufacturing a chip package according to one or more example embodiments. FIGS. 6A, 6B, 6C and 6D are diagrams illustrating intermediate steps of a method of manufacturing the chip package illustrated in FIG. 3 according to one or more example embodiments.

Together with reference to FIGS. 3, 5 and 6B, a method of manufacturing a chip package 100 includes: in step S110, a flexible substrate 110 is provided. The flexible substrate 110 may include a bottom surface 110B, a side wall 110S and a top surface 110U. The top surface 110U of the flexible substrate 110 may include a central region C and an edge region E surrounding the central region C.

Next, in step S120, with reference to FIG. 6A, a first heat dissipation part 120 is disposed on the flexible substrate 110. The first heat dissipation part 120 may include a body part 121 and a wing part 122 connected at both sides of the body part 121. In one or more example embodiments, the providing the first heat dissipation part 120 may include: providing a body part 121 on the bottom surface 110B of the flexible substrate 110, enabling the wing part 122 to extend from the body part 121 to the top surface 110U of the flexible substrate 110 along the side wall 110S of the flexible substrate 110, and enabling the wing part 122 to cover the edge region E of the top surface 110U of the flexible substrate 110.

In one or more example embodiments, as illustrated in FIGS. 6B, 6C and 6D, the top surface 110U of the flexible substrate 110 may further include: a peripheral region P, surrounding the edge region E; and a trench T, disposed in the peripheral region P at both sides of the flexible substrate 110. In one or more example embodiments, the providing the first heat dissipation part 120 may further include: enabling the wing part 122 of the first heat dissipation part 120 to pass through the trench T along a vertical direction, and enabling the wing part 122 to be bent along a horizontal direction to cover the edge region E of the top surface 110U of the flexible substrate 110.

Next, in step S130, with reference to FIG. 3, a semiconductor chip 130 is disposed on the top surface 110U of the flexible substrate 110.

In one or more example embodiments, with reference to FIG. 3, the flexible substrate 110 may include: a base film 111, formed of a flexible material; a wiring layer 112, disposed on an upper surface of the base film 111; and a solder resist 113, covering the wiring layer 112. In one or more example embodiments, an upper surface 130U of the semiconductor chip 130 may be a passive surface, and a lower surface 130B of the semiconductor chip 130 may be an active surface. In one or more example embodiments, the providing the semiconductor chip 130 may include: connecting the semiconductor chip 130 to the wiring layer 112 via a conductive bump B disposed on the active surface, and providing an underfill material U to be between the semiconductor chip 130 and the flexible substrate 110, such that the underfill material U surrounds the conductive bump B.

Next, in step S140, with reference to FIG. 3, a heat dissipation glue 150 may be disposed on a lower surface of the second heat dissipation part 140; and in step S150, the second heat dissipation part 140 may be provided on the semiconductor chip 130 and the flexible substrate 110. The second heat dissipation part 140 may cover the upper surface 130U of the semiconductor chip 130 and a portion of the wing part 122 of the first heat dissipation part 120 covering the edge region E of the top surface 110U of the flexible substrate 110.

In one or more example embodiments, as illustrated in FIG. 3, the second heat dissipation part 140 may include a central portion 140C and an edge portion 140E. In one or more example embodiments, the providing the second heat dissipation part 140 may include: enabling the central portion 140C to contact the upper surface 130U of the semiconductor chip 130 via the heat dissipation glue 150, and enabling the edge portion 140E to contact the portion of the wing part 122 of the first heat dissipation part 120 covering the edge region E of the top surface 110U of the flexible substrate 110 via the heat dissipation glue 150.

In one or more example embodiments, as illustrated in FIG. 3, the providing the first heat dissipation part 120 may further include coupling the first heat dissipation part 120 to the flexible substrate 110 through the heat dissipation glue 150, but one or more example embodiments are not limited thereto.

FIGS. 7A and 7B are diagrams illustrating intermediate steps of a method of manufacturing the chip package illustrated in FIG. 4 according to one or more example embodiments. Unlike the process illustrated in FIGS. 6A, 6B, 6C and 6D, the process illustrated in FIGS. 7A-7B is distinguished in that: the heat dissipation glue 150 may not be disposed between a first heat dissipation part 220 and a flexible substrate 210. In one or more example embodiments, as illustrated in FIGS. 7A and 7B, the providing the first heat dissipation part 220 may include: coupling the first heat dissipation part 220 to the flexible substrate 210 through an electroplating process.

According to one or more example embodiments, through the heat dissipation glue 150, it is possible to connect the semiconductor chip 130 to the second heat dissipation part 140, and then connect the second heat dissipation part 140 to the first heat dissipation part 220, to form a heat dissipation path. Through the method of manufacturing the chip package according to one or more example embodiments, it is possible to obtain a package having a heat dissipation structure which may expand a heat dissipation area in direct contact with a surface of the chip through the first heat dissipation part located on the bottom surface, the side wall and the top surface of the flexible substrate and the second heat dissipation part connected to the upper surface of the COF-type semiconductor chip and the edge of the first heat dissipation part, thereby improving the heat dissipation effect.

Although one or more example embodiments have been illustrated and described above, it will be apparent to those skilled in the art that various modifications and changes in form and details may be made therein without departing from the spirit and scope of the following claims.

1. A chip package comprising:
a flexible substrate comprising:
a bottom surface;
a side wall; and
a top surface comprising a central region and an edge region around the central region;
a first heat dissipation part comprising:
a body part; and
a wing part on the bottom surface of the flexible substrate and extending from opposite ends of the body part to the top surface of the flexible substrate along the side wall of the flexible substrate, the wing part covering the edge region of the top surface of the flexible substrate;
a semiconductor chip on the top surface of the flexible substrate;
a second heat dissipation part covering an upper surface of the semiconductor chip, and a portion of the wing part of the first heat dissipation part that covers the edge region of the top surface of the flexible substrate; and
a heat dissipation glue on a lower surface of the second heat dissipation part,
wherein the heat dissipation glue connects the semiconductor chip to the second heat dissipation part and connects the second heat dissipation part to the first heat dissipation part, to form a heat dissipation path.

2. The chip package of claim 1, wherein the second heat dissipation part comprises:
a central portion; and
an edge portion,
wherein the heat dissipation glue is provided between the central portion and the upper surface of the semiconductor chip, and
wherein the heat dissipation glue is provided between the edge portion and a portion of the first heat dissipation part.

3. The chip package of claim 2, wherein the top surface of the flexible substrate further comprises:
a peripheral region around the edge region; and
a trench in the peripheral region at two sides of the flexible substrate, and
wherein the wing part of the first heat dissipation part passes through the trench in a vertical direction, and then is bent in a horizontal direction to cover the edge region of the top surface of the flexible substrate.

4. The chip package of claim 1, wherein the heat dissipation glue is further provided between the flexible substrate and the first heat dissipation part.

5. The chip package of claim 1, wherein the first heat dissipation part is coupled to the flexible substrate through an electroplating layer.

6. The chip package of claim 5, wherein a thickness of the electroplating layer is in a range of 25 μm to 35 μm.

7. The chip package of claim 1, wherein each of the first heat dissipation part and the second heat dissipation part comprises a metal.

8. The chip package of claim 7, wherein a thickness of the first heat dissipation part is in a range of 25 μm to 35 μm.

9. The chip package of claim 3, wherein the flexible substrate comprises:
a base film comprising a flexible material;
a wiring layer, on an upper surface of the base film; and
a solder resist covering the wiring layer.

10. The chip package of claim 9, wherein the solder resist is provided in the central region and the edge region, and is not provided in the peripheral region.

11. The chip package of claim 9, wherein the upper surface of the semiconductor chip is a passive surface,
wherein a lower surface of the semiconductor chip is an active surface, and
wherein the semiconductor chip is connected to the wiring layer via a conductive bump on the active surface.

12. The chip package of claim 11, wherein an underfill material is between the semiconductor chip and the flexible substrate, and
wherein the underfill material is around the conductive bump.

13. The chip package of claim 1, wherein the first heat dissipation part does not contact the semiconductor chip.

14. The chip package of claim 13, wherein a portion of the first heat dissipation part is separated from the side wall of the semiconductor chip in a horizontal direction.

15.-20. (canceled)
